(19) United States
(12) Patent Application Publication
(10) Pub. No.: US 2006/0118780 A1
(43) Pub. Date: Jun. 8, 2006

(54) Organo-resistive memory unit

(76) Inventors: Axel Gerlt, Furth (DE); Wolfgan Clemens, Furth (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 10/541,815

(22) PCT Filed: Dec. 9, 2003
(86) PCT No.: PCT/DE03/04052

§ 371 Date: Jul. 8, 2005

(30) Foreign Application Priority Data
Jan. 9, 2003 (DE) 103005218

(51) Int. Cl. H01L 29/08

(52) U.S. Cl. 257/40

(57) ABSTRACT

The invention provides, for the first time, the possibility of producing an organic memory unit within a known production process for organic electronic components, because the memory unit is composed of substantially the same organo-resistive materials as are the organic electronic components themselves. Moreover, the invention discloses a circuit component by means of which any desired memory unit, that is to say, a volatile or non-volatile, write-once or rewritable memory unit can be equally well produced in a known production process.

The invention relates to a memory unit for organic electronics, and electronics circuitry therefor.

Memory units are known which are needed for nearly all electronic components. In conventional “silicon electronics”, a number of principles of storage are known, both volatile (eg DRAM), and non-volatile (eg flash). In the case of the non-volatile memory units one must further differentiate between writing a memory once only (WORM: write once read many) and R/W: reading and writing at will. However, these known types cannot be employed in the novel “polymer electronics” (although it could not have been assumed from the term “polymer” that small molecules are also employed), nor for integrated electronics circuits based on organic semiconductors or, under certain circumstances, on organic conductors and insulators.

Organic memory units are also known, eg those sold by Thin Film Electronics (www.thinfilm.se), but these are all associated with conventional silicon electronics or are read in some other manner, eg optically or magnetically.

It is therefore an object of the invention to provide a memory unit which can be integrated into organic electronics such that production thereof can be included in the production process of some other organic component. The cost of such a memory unit could be considerably lower than that of a conventional memory unit.

The invention relates to a memory unit which is composed of substantially organic material, the memory function of the component being effected in that an organo-resistive material embedded in an electrolyte is utilized as a memory device. The invention further relates to a circuit plan for a memory unit, of which the circuit arrangement lies between a ground and a supply voltage and comprises at least one resistor, an organo-resistive conductive element, embedded in an electrolyte, and a control electrode.

The prior organic conductive materials, such as, for example, polyaniline, emeraldine salt (PANI) or PE-/PSS are based on conjugated carbon chains, which are rendered electrically conductive by doping with a further material (eg an acid). These materials typically have the property that both their color and their electrical resistance change as a result of electrochemical reactions (electrochromic effect) . The change in resistance, which typically occurs in a redox reaction, is very large, and the resistance (and with it the conductivity) is in this case altered by several orders of magnitude from one redox state to the other. These materials are called “organo-resistive”. The change in conductivity and/or color is very simple to detect. Depending on which process is utilized, the reaction is reversible or irreversible.

This effect is presently utilized for designing memory units.

In the circuit described below with reference to FIG. 2, a conductive element composed of the organic conductive material is integrated in such a manner that the application of an electrical potential causes it to become conductive or (substantially) non-conductive, which happens reversibly or irreversibly. By means of specific circuitry, this effect can then be read out as a signal (0 or 1). In some cases it might even be possible to set mean values, ie mean resistance values, so as to achieve a higher storage density (eg 4 bits per unit), as this is in principle also done in some methods of flash storage.

Suitable materials for the memory unit are all materials that change their resistance value due to electrochemical reactions, but especially all organic semiconductor materials which can be rendered conductive by means of doping. This principle is not restricted to polymers. Known electrochromic materials, for example PE-/PSS or PANI, are being employed successfully.

For the choice of material, however, it is not the electrochromic effect which is crucial, but the electrically adjustable change in resistance. Thus, in principle, all intrinsically conductive and semiconducting organic materials can be used, in addition to the abovementioned PE- and PANI, for instance, polypyrrole, polythiophene, polyfluorene, PPV, PTV or mixtures thereof or in admixture with other materials (which are used, for example, for doping), that is to say, mixed compounds thereof or alternatively relatively small molecules such as pentacene or tetracene. As a rule, therefore, all organic-based molecules which contain conjugated chains. In this case, a “doping agent” is usually admixed in order to increase the conductivity. It is advantageous if these materials are soluble in solvents and can accordingly be produced using the same processes as those with which organic transistors and circuits are produced. Printing processes are of particular interest in this context.

Due to the material used, the production of the memory can be readily integrated into the process for the production of organic electronic components.

The invention is described in greater detail below with reference to two figures showing preferred embodiments.

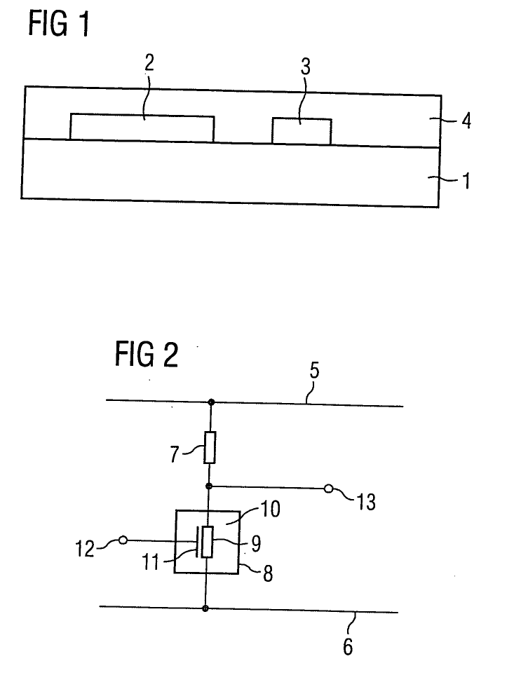

FIG. 1 shows the basic construction of the organo-resistive memory, and

FIG. 2 shows a proposed circuit for operating and reading the memory.

FIG. 1 shows a cross-section through an organo-resistive memory indicating that organo-resistive material 2 is applied in structured form to a substrate 1. A conductive layer 3 is likewise applied in structured form to substrate 1 such that it has no direct contact with material 2.

This illustrates a side-by-side design, but a vertical design is equally possible in which the two layers 2 and 3 again lie on the substrate but in superposition, being separated from one another only by an electrolyte layer 4. Which of the two layers is directly adjacent the substrate and which forms the “top” layer separated only by the electrolyte from the “bottom” layer adjacent the substrate is of no consequence. Other perfectly conceivable possibilities include, for example, those in which the substrate is not at the bottom but, rather, at the side or at the top. At all events, a superimposed arrangement, as considered perpendicularly to the substrate, is just as realizable as the side-by-side arrangement described herein and shown in the figure, in which the two materials lie parallel to the substrate and are at the same level.

The two structured layers 2 and 3 are embedded in an electrolyte layer 4. Electrolyte layer 4 can be liquid or solid, provided ions can flow through it. There are, for example, solid electrolytes, such as polymer electrolytes, which are suitable for this purpose.

Applying an electrical voltage between 2 and 3 initiates an ionic current through 4, whereby organo-resistive material 2 is either oxidized or reduced and is thus rendered conductive or non-conductive. With most of the organo-resistive materials, the color thereof changes with their conductivity, so that these materials also open up the possibility of designing memory units which may additionally be read optically.

FIG. 2 shows a circuit arrangement for operation and readout of the memory:

the circuit arrangement is provided between a supply voltage 5 and ground 6 and consists of a resistor 7, which may, for example, be in the form of a controllable organic transistor (eg an OFET), and an organo-resistive element 8 acting as voltage divider. Organo-resistive element 8 in turn consists of an organo-resistive conductive element 9 and a control electrode 11, which are both surrounded by an electrolyte 10 (or covered by a layer of electrolyte). With the aid of a control electrode 11, the resistance of resistor 9 can now be varied by means of a voltage 12 (also called an excitation voltage) by means of an ionic current flowing through electrolyte 10. This variation in turn causes a change in the potential between 8 and 7, which can be tapped at an output point 13. It is thus possible to read out the state of the memory (logic 1 or 0 or additionally intermediate values) by way of the potential at 13. In this case, a high potential is present at 13 when the organo-resistive element shows a higher impedance than 7, and a low potential is present when said impedance is lower than that of 7.

This basic module can be utilized as desired in a circuit or in a customized arrangement (eg a matrix-like design) so that, depending on the selection of materials and the choice of excitation voltages, a volatile or non-volatile, write-once or rewritable memory will be obtained.

To achieve greater storage densities, a matrix design of the individual memory units is also possible, as is already known from other principles of storage (eg DRAM).

The invention provides, for the first time, the possibility of producing an organic memory within a known production process for organic electronic components, because the memory is constructed from substantially the same organo-resistive materials as the organic electronic components themselves. Moreover, the invention discloses a circuit component by means of which any desired memory unit, that is to say, a volatile and non-volatile, write-once or rewritable memory unit, can be equally well produced in a known production process.

1. A memory unit composed substantially of organic material, wherein the storage function of the component is achieved due to an organo-resistive material being embedded in an electrolyte.

2. A memory unit as defined in claim 1, wherein said organo-resistive material is separated from a conductive material by an electrolyte so that the flow of ionic current through the electrolyte due to application of a voltage to the conductive material causes a readable change in the conductance and/or color of the organo-resistive material.

3. A memory unit as defined in claim 1 or claim 2, wherein the organo-resistive material is disposed in structured form on a substrate.

4. A memory unit as defined in any one of the previous claims, wherein said organo-resistive materials are based on conjugated chains.

5. A memory unit as defined in any one of the previous claims, wherein the electrolyte is water-based and/or solid.

6. A memory unit as defined in any one of the previous claims, wherein the organo-resistive material and/or a mixture of said materials is/are soluble and can be processed in solution.

7. Electronics circuitry for a memory unit, wherein the circuit arrangement is provided between a ground and a supply voltage and comprises at least one resistor, an organo-resistive conductive element, embedded in an electrolyte, and a control electrode.

8. Electronics circuitry as defined in claim 7, wherein the design of the memory unit provides a matrix arrangement for achieving a higher storage density.
